(19) United States
(12) Patent Application Publication
(10) Pub. No.: US 2022/0219282 A1
(43) Pub. Date: Jul. 14, 2022

(54) METHOD AND APPARATUS WITH POLISHING PAD CONDITIONING SIMULATION

(71) Applicant: RESEARCH & BUSINESS FOUNDATION SUNGKYUNKWAN UNIVERSITY, Suwon-si (KR)

(72) Inventors: TAESUNG KIM, Seoul (KR); EUNGCHUL KIM, Suwon-si (KR)

(73) Assignee: RESEARCH & BUSINESS FOUNDATION SUNGKYUNKWAN UNIVERSITY, Suwon-si (KR)

(21) Appl. No.: 17/574,961

(22) Filed: Jan. 13, 2022

(30) Foreign Application Priority Data
Jan. 13, 2021 (KR) 10-2021-0004464

(51) Int. Cl. B24B 37/005; G06F 30/20

(52) U.S. Cl. CPC B24B 37/005; G06F 30/20

(57) ABSTRACT

A polishing pad conditioning simulation method and apparatus are provided. The polishing pad conditioning simulation method includes extracting first characteristic information including process parameters of the conditioning, extracting second characteristic information including structure information of a conditioner, and extracting third characteristic information including structure information of a polishing pad, inputting the first characteristic information, the second characteristic information, and the third characteristic information to an algorithm, calculating a profile of the polishing pad, and displaying data based on the calculated profile of the polishing pad.

### CROSS-REFERENCE TO RELATED APPLICATIONS

This application claims the benefit under 35 USC § 119(a) of Korean Patent Application No. 10-2021-0004464, filed on Jan. 13, 2021, in the Korean Intellectual Property Office, the entire disclosure of which is incorporated herein by reference for all purposes.

### BACKGROUND

### 1. Field

The following description relates to a method and apparatus with polishing pad conditioning simulation.

### 2. Description of Related Art

With the development of new-generation semiconductors and the demand for miniaturization and high capacity of products, semiconductor devices have become more highly integrated. In order to easily form a pattern on a wafer for the highly integrated semiconductor device, a chemical mechanical polishing/planarization (CMP) process to planarize the wafer surface may be performed to maintain a step and roughness within a depth of focus (DOF) range. In the CMP process, as illustrated in FIG. 1, slurry containing an abrasive and a chemical may be continuously supplied to a rotating polishing pad through a nozzle, and the wafer may be chemically and mechanically polished using the polishing pad and the components of the slurry.

In this example, the polishing performance may vary greatly depending on materials, roughness, porosity, grooves, and the like of the pad. Materials such as residues, foreign substances, aggregated abrasives, and pad debris generated while polishing the wafer may be elements that block pores constituting the pad or may cause scratches on the wafer embedded in the pores.

Additionally, if the pores are blocked, the flow of the slurry may become unstable, which may deteriorate polishing performance. Therefore, in order to maintain the pad in a new and uniform state to prevent this phenomenon, the conditioning process may be performed simultaneously with or before and after the polishing process.

The conditioning process may be performed by applying a pressure to a conditioner consisting of grits to grind a diamond and the like, and grinding the pad surface corresponding to the pad area through rotation and sweeping. At this time, the uniformity and a profile of the pad may be determined by a trajectory of the conditioner by the speed distribution according to a rotation speed of the pad, a rotation speed of the conditioner, a sweep range and a sweep zone; process parameters including pressure applied to the conditioner and a process time; structural parameters of the conditioner including the number, size, shape and arrangement of diamonds; structural characteristics of pad including the groove number, a groove shape, a groove depth, and elasticity of pad; an effect of slurry including changes in physical properties of the pad by the used slurry; and effects on a pressure distribution that occurs in a process of passing the conditioner on the pad while being in contact with the pad.

Typically, the conditioning process may be performed non-uniformly in the linear density illustrated in FIG. 3, and due to these differences, a wear density difference may occur locally, thereby forming an uneven profile. When such a non-uniform conditioning process continues, the deteriorated imbalance in the pad profile may be caused to generate a difference in physical contact with the pad over the entire wafer range, thereby reducing wafer polishing uniformity.

Additionally, typically, for the flatness of the entire pad area, the conditioner may sweep in a range out of a pad edge. However, since a pressure difference may occur locally in the conditioner out of the pad edge, the grinding rate in a specific area rapidly increases due to the influence of the accumulated linear density and pressure distribution, thereby forming a deep dished area as illustrated in FIG. 3. At this time, residue or debris generated in the process may be left in the generated dished area, and then may be re-introduced to act as a factor that causes scratches on the wafer.

In order to prevent these problems, the conditioning process should be evaluated so that the pad has an overall flat profile before the polishing process is performed. In order to improve the flatness, all factors capable of affecting the profile of the pad described above need to be considered.

However, in order to measure the profile of the pad, the cross section thereof should be measured by separating the pad from a table and cutting the separated pad to pass through the center, so that the reuse after evaluation is impossible and there is a non-economical problem. In order to improve the above problem, typically, there is proposed a method of measuring a profile of the pad surface without separating the pad from the table, but since the profile can be measured only in a specific radial direction, the profile corresponding to the entire pad area cannot be evaluated.

Additionally, there are examples of simulating the conditioning process, but the characteristics of the conditioner and the pad are not reflected, the simulation is impossible as long as an actual process time, and the grinding amount is not presented. As a result, there was a problem that an accurate profile could not be presented, and an evaluated range was extremely limited.

The above information is presented as background information only to assist with an understanding of the present disclosure. No determination has been made, and no assertion is made, as to whether any of the above might be applicable as prior art with regard to the disclosure.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In a general aspect, a polishing pad conditioning simulation method includes extracting first characteristic information comprising process parameters of the conditioning, extracting second characteristic information comprising structure information of a conditioner, and extracting third characteristic information comprising structure information of the polishing pad; inputting the first characteristic information, the second characteristic information, and the third characteristic information to an algorithm; calculating a profile of the polishing pad; and outputting data based on the calculated profile of the polishing pad.

The inputting to the algorithm may further include inputting characteristic information based on a pressure distribution applied to the polishing pad to the algorithm.

The inputting to the algorithm may further include inputting slurry characteristic information comprising a change in physical properties of the polishing pad by slurry implemented in the conditioning of the polishing pad.

The calculating may include determining coordinates of diamond grits included in the conditioner, determining a pressure on each diamond grit, and determining an indentation depth for each diamond grit.

The calculating may include accumulating a wear density in a mesh corresponding to the coordinates of each grit of the diamond comprised in the conditioner.

The algorithm may be configured to derive a trajectory of grinding the pad by diamond grits of the conditioner based on the first characteristic information, the second characteristic information, and the third characteristic information, and calculate grinding amount information on an amount of grinding of the polishing pad by each grit of the diamond based on the trajectory, the first characteristic information, the second characteristic information, and the third characteristic information.

The profile of the polishing pad may include a wear density in the polishing pad, a trajectory of diamond grits of the conditioner, and cumulative moving distance information of each diamond.

The structure information of the conditioner may be extracted based on an apparatus comprising confocal microscopy and atomic force microscopy (AFM); the first characteristic information may include rotation speed information of the polishing pad and the conditioner, sweep arm operation information, pressure information, and press time information; the second characteristic information may include density and size information of the conditioner, and diamond information, and the third characteristic information may include groove information, hardness information, and size information of the polishing pad.

In a general aspect, a polishing pad conditioning simulation apparatus includes an extraction device configured to extract first characteristic information comprising progress parameters for the conditioning, extract second characteristic information comprising structure information of a conditioner, and extract third characteristic information comprising structure information of the polishing pad a calculation device configured to calculate a profile of the polishing pad by inputting the first characteristic information, the second characteristic information and the third characteristic information to an algorithm; and a display unit configured to display data based on the calculated profile of the polishing pad.

The calculation device may be configured to calculate the profile of the polishing pad by further inputting characteristic information according to a pressure distribution applied to the polishing pad to the algorithm.

The calculation device may be configured to calculate the profile of the polishing pad by further inputting slurry characteristic information including a change in physical properties of the polishing pad by slurry implemented in the conditioning of the polishing pad.

The calculation device may be configured to determine coordinates of diamond grits included in the conditioner, determine a pressure on each diamond grit, and determine an indentation depth for each diamond grit.

The calculation device may be configured to accumulate a wear density in a mesh corresponding to the coordinates of each grit of the diamond comprised in the conditioner.

The algorithm may be configured to derive a trajectory of grinding the pad by diamond grits of the conditioner based on the first characteristic information, the second characteristic information, and the third characteristic information, and calculate grinding amount information on an amount of grinding of the polishing pad by each grit of the diamond based on the trajectory, the first characteristic information, the second characteristic information, and the third characteristic information.

The profile of the polishing pad comprises a wear density in the polishing pad, a trajectory of each diamond grit of the conditioner, and cumulative moving distance information of each diamond.

The structure information may be extracted based on an apparatus comprising confocal microscopy and atomic force microscopy (AFM); the first characteristic information comprises rotation speed information of the polishing pad and the conditioner, sweep arm operation information, pressure information, and press time information, the second characteristic information comprises density and size information of the conditioner, and diamond information, and the third characteristic information comprises groove information, hardness information, and size information of the polishing pad.

Other features and aspects will be apparent from the following detailed description, the drawings, and the claims.

### BRIEF DESCRIPTION OF DRAWINGS

FIG. 1 is a schematic diagram of an example CMP process, in accordance with one or more embodiments.

FIG. 2 is a diagram illustrating a non-uniform linear density shown in a conditioning process of a typical CMP process.

FIG. 3 is a diagram illustrating a dished area to be expressed under a specific condition of an example conditioning process of an example polishing pad, in accordance with one or more embodiments.

FIG. 4 is a flowchart time-sequentially illustrating an example simulation method to condition an example polishing pad, in accordance with one or more embodiments.

FIGS. 5A and 5B illustrate an operation of extracting information in the example simulation method to condition the example polishing pad, in accordance with one or more embodiments.

FIGS. 6A and 6B illustrate characteristics according to a pressure distribution in an example simulation method to condition an example polishing pad, in accordance with one or more embodiments.

FIGS. 7A to 7D illustrate characteristics according to a pressure distribution in an example simulation method to condition an example polishing pad, in accordance with one or more embodiments.

FIG. 8 illustrate an example of determining diamond grit coordinates included in an example conditioner in an example simulation method to condition an example polishing pad, in accordance with one or more embodiments.

FIGS. 9A to 9C illustrate an example of determining coordinates according to second characteristic information in an example simulation method to condition an example polishing pad, in accordance with one or more embodiments.

FIGS. 10A and 10B illustrate an example of measuring a size and a contact area of a diamond grit of an example conditioner, and calculating an indentation depth according to the size and the contact area in an example simulation method to condition an example polishing pad, in accordance with one or more embodiments.

FIG. 11 illustrates a first simulation result implementing an example simulation method to condition an example polishing pad, in accordance with one or more embodiments.

FIG. 12 illustrates a second simulation result implementing an example simulation method to condition an example polishing pad, in accordance with one or more embodiments.

FIG. 13 illustrates a third simulation result implementing an example simulation method to condition an example polishing pad, in accordance with one or more embodiments.

FIG. 14 illustrates a fourth simulation result implementing an example simulation method to condition an example polishing pad, in accordance with one or more embodiments.

FIG. 15 illustrates a fifth simulation result implementing an example simulation method to condition an example polishing pad, in accordance with one or more embodiments.

FIGS. 16A to 16D illustrate a result of comparing a profile of an actual polishing pad with a sixth simulation result implementing an example simulation method to condition an example polishing pad, in accordance with one or more embodiments.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known after an understanding of the disclosure of this application may be omitted for increased clarity and conciseness, noting that omissions of features and their descriptions are also not intended to be admissions of their general knowledge.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

Throughout the specification, when an element, such as a layer, region, or substrate is described as being “on,” “connected to,” or “coupled to” another element, it may be directly “on,” “connected to,” or “coupled to” the other element, or there may be one or more other elements intervening therebetween. In contrast, when an element is described as being “directly on,” “directly connected to,” or “directly coupled to” another element, there can be no other elements intervening therebetween.

The terminology used herein is for the purpose of describing particular examples only, and is not to be used to limit the disclosure. As used herein, the singular forms “a,” “an,” and “the” are intended to include the plural forms as well, unless the context clearly indicates otherwise. As used herein, the term “and/or” includes any one and any combination of any two or more of the associated listed items. As used herein, the terms “include,” “comprise,” and “have” specify the presence of stated features, numbers, operations, elements, components, and/or combinations thereof, but do not preclude the presence or addition of one or more other features, numbers, operations, elements, components, and/or combinations thereof.

In addition, terms such as first, second, A, B, (a), (b), and the like may be used herein to describe components. Each of these terminologies is not used to define an essence, order, or sequence of a corresponding component but used merely to distinguish the corresponding component from other component(s).

Throughout this specification, it will be understood that when a certain member is located “on”, “above”, “at the top of”, “under”, “below”, and “at the bottom of” the other member, a certain member is in contact with the other member and another member may also be present between the two members.

Unless otherwise defined, all terms, including technical and scientific terms, used herein have the same meaning as commonly understood by one of ordinary skill in the art to which this disclosure pertains and after an understanding of the disclosure of this application. Terms, such as those defined in commonly used dictionaries, are to be interpreted as having a meaning that is consistent with their meaning in the context of the relevant art and the disclosure of this application, and are not to be interpreted in an idealized or overly formal sense unless expressly so defined herein.

Also, in the description of example embodiments, detailed description of structures or functions that are thereby known after an understanding of the disclosure of the present application will be omitted when it is deemed that such description will cause ambiguous interpretation of the example embodiments.

An object to be achieved by the one or more examples is to provide a simulation method and apparatus to condition a polishing pad that proposing a conditioning process at a grinding rate and flatness of a polishing pad optimized in a CMP process.

An object to be achieved by the present disclosure is to provide a result with high reliability as accurate values with units by measuring and using non-simplified actual variable values.

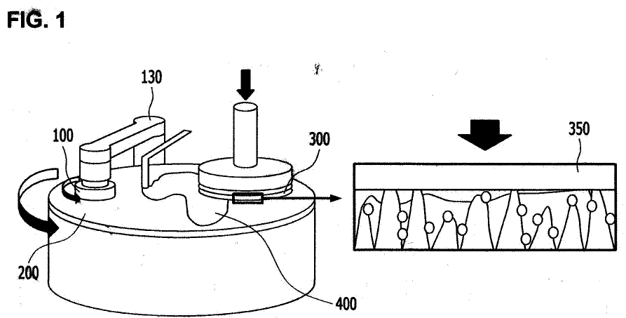

FIG. 1 illustrates a schematic diagram of an example CMP process.

Semiconductor chips and the like may be manufactured through masking, etching, insulating layer forming, and metal wiring forming processes, but as high performance and high integration of the semiconductor chips are continuously made, a more advanced manufacturing method may be desirable. Herein, it is noted that use of the term ‘may’ with respect to an example or embodiment, e.g., as to what an example or embodiment may include or implement, means that at least one example or embodiment exists where such a feature is included or implemented while all examples and embodiments are not limited thereto.

In particular, recent semiconductor chips have implemented a multi-layered wiring structure for high integration and microminiaturization, and proper planarization may be beneficial in forming the multi-layered wiring structure.

Referring to FIG. 1, a method mainly implemented for planarization of a wafer 350 is a polishing process called chemical mechanical polishing/planarization (CMP). The CMP is a process that removes the surface layer of the semiconductor wafer 350 by combining chemical action with physical polishing, and mechanically/chemically polishing the surface of the wafer 350 by a mechanical component of friction force and a chemical component in a slurry 400 solution.

The CMP process may be simply an operation of flatly grinding a specific film on the semiconductor wafer 350, and in the CMP process, the uniformity of the polishing pad 200 to grind the wafer 350 is also very important. In order to achieve the flat uniformity of the polishing pad 200, the conditioning process is performed on the polishing pad 200 in combination.

However, in order to measure the profile of the polishing pad 200 when it is subjected to the conditioning process, the pad 200 is separated from the table and cut to pass through the center of the pad 200, and then the cross-section is measured. Accordingly, a non-economic problem may occur in that the reuse after evaluation may not be possible. An object of the example simulation method and apparatus to condition the polishing pad, in accordance with one or more embodiments, may be to solve such an uneconomical problem. However, the one or more examples are not limited thereto.

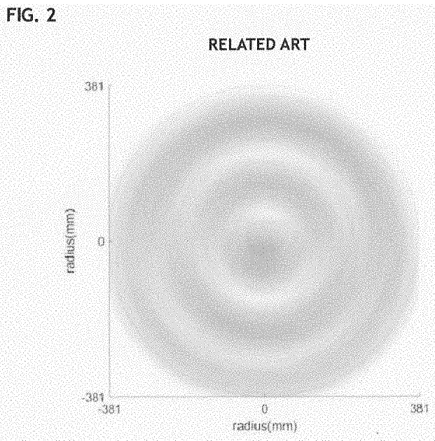

FIG. 2 illustrates a non-uniform linear density shown in a conditioning process of a typical CMP process.

Referring to FIG. 2, it can be understood that the linear density of the polishing pad 200 that performs a typical conditioning process may be non-uniform. The reason is that respective diamond grits included in a disk of a conditioner 100 that performs the conditioning process move by three types of rotations (rotation of the conditioner 100, rotation of a sweep arm 130, and rotation of a polishing head 300).

The simulation method and apparatus to condition the polishing pad, in accordance with one or more embodiments may solve a non-uniform linear density in general process conditions by these three types of rotations. However, the examples are not limited thereto.

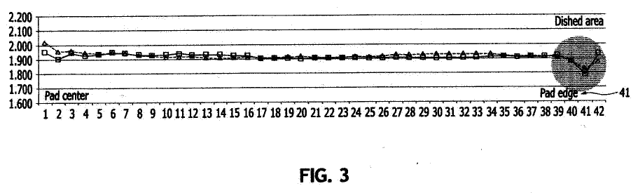

FIG. 3 illustrates a dished area to be expressed under a specific condition of a conditioning process of a polishing pad, in accordance with one or more embodiments.

Referring to FIG. 3, for the flatness of the entire area of the pad, the conditioner 100 performs the sweeping of the sweep arm 130 in a range out of a pad edge. However, since a pressure difference may occur locally in the conditioner 100 out of the pad edge, a grinding rate in a specific area may rapidly increase due to the influence of the accumulated linear density and pressure distribution, thereby forming a deep dished area in a pad edge 41.

The deep dished area becomes an element that generates scratches on the wafer 350 by increasing the possibility that residue, debris, etc. generated during the CMP process are left and then introduced again.

The simulation method and apparatus to condition the polishing pad, in accordance with one or more embodiments, considers all factors that may affect the profile of the polishing pad 200 during simulation, thereby improving the typical inaccurate simulation method with respect to the pad edge 41. However, the examples are not limited thereto.

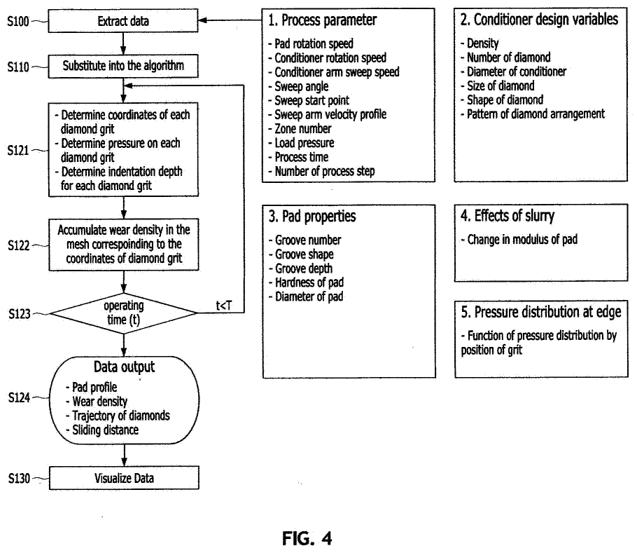

FIG. 4 is a flowchart time-sequentially illustrating an example simulation method to condition a polishing pad, in accordance with one or more embodiments.

Referring to FIG. 4, the example simulation method to condition the polishing pad, in accordance with one or more embodiments, may include an operation (operation S100) of extracting first characteristic information including structure information of the polishing pad 200, second characteristic information including structure information of the conditioner 100, and third characteristic information including structure information of the sweep arm 130.

The first characteristic information to the third characteristic information may be divided into, for example, progress parameters (rotation speed of the pad, rotation speed of the conditioner, etc.), shape (form and pattern) information of the conditioner, a shape (form and pattern) and properties of the pad, etc. However, the examples are not limited thereto. In an example, the characteristic information may be classified based on information on the polishing pad 200, the conditioner 100, and the sweep arm 130.

Referring to FIG. 4, the characteristic information may be classified to process parameters, conditioner design variables, pad properties, effects of slurry, and pressure distribution at an edge, and thus, for the unification of description, the examples will be described below based on the above classification.

Accordingly, in accordance with one or more embodiments, the first characteristic information may include information on factors affecting a pad profile when performing the conditioning process. Accordingly, the conditioning progress parameter may include, for example, a pad rotation speed of the polishing pad 200, a conditioner rotation speed of the conditioner 100, operation information of the sweep arm 130, pressure information, and process time information.

The operation information of the sweep arm 130 may include a sweep arm sweep speed of the sweep arm 130, a sweep angle of the sweep arm 130, a sweep start point of the sweep arm 130, a sweep arm velocity profile of the sweep arm 130, a zone number, a sweep speed at each zone number of the sweep arm 130.

Additionally, the pressure information may include, for example, a load pressure at which the conditioner 100 presses toward the polishing pad 200, a pressure at which the polishing head 300 presses toward the polishing pad 200, and the like, and the process time information may include a process time, number of process step information, and the like. However, the examples are not limited thereto.

Additionally, in accordance with one or more embodiments, the second characteristic information may include structure information of the conditioner 100. Accordingly, the second characteristic information may include density and size information of the conditioner 100, and diamond information.

In other words, the second characteristic information may include, for example, a density of the conditioner 100, a diameter of the conditioner, and the like.

Meanwhile, the above-described diamond information may include, for example, a size of the diamond, the number of diamonds included in the conditioner 100, a shape of the diamond, and a pattern of diamond arrangement, and the like. However, the examples are not limited thereto.

Additionally, in accordance with one or more embodiments, the third characteristic information may include structure information of the polishing pad 200. Accordingly, the third characteristic information may include groove information, hardness of pad, and size information of the polishing pad 200.

Specifically, the groove information of the polishing pad 200 may include, for example, the groove number, a groove shape (form, feature, and shape), and groove depth information.

Additionally, the size information of the polishing pad 200 may include, for example, a diameter of the pad. However, the examples are not limited thereto.

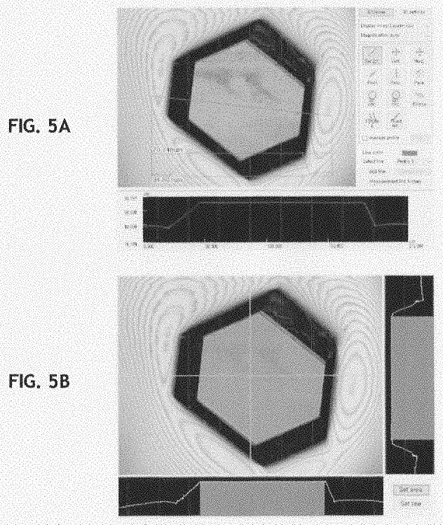

FIG. 5 illustrates an operation (operation S100 of FIG. 4) of extracting information in the simulation method to condition an example polishing pad, in accordance with one or more embodiments.

Referring to FIG. 5, the operation (operation S100) of extracting information in the example simulation method to condition the polishing pad, in accordance with one or more embodiments, may be a method that implements an apparatus such as, but not limited to, atomic force microscopy (AFM), confocal microscopy, and a scanning electron microscope (SEM), which can measure a minute topography of an object.

In an example, FIG. 5 illustrates a process of measuring the grit structure and shape of a diamond included in the conditioner 100 through confocal microscopy. However, the examples are not limited thereto. In an example, the first characteristic information, the second characteristic information, and the third characteristic information may also be information extracted with an apparatus that measures a minute topography of an object.

Additionally, in accordance with one or more embodiments, physical property information including elastic moduli of the polishing pad 200 and diamonds of the conditioner 100, and the like may be extracted using atomic force microscopy (AFM). However, the examples are not limited thereto.

That is, in accordance with one or more embodiments, the extracting operation (operation S100) may include extracting information by measuring minute structures (forms, shapes, patterns) of the polishing pad 200, the conditioner 100, and the sweep arm 130 based on at least one of AFM, confocal microscopy, and SEM. However, the examples are not limited thereto.

In other words, in accordance with one or more embodiments, the extracting operation (operation S100) may acquire structure information including a minute topography of the object, and the second characteristic information may implement the conditioner 100 as an object, and the third characteristic information may implement the polishing pad 200 as an object. However, the examples are not limited thereto.

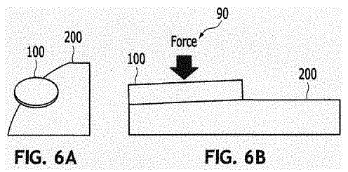

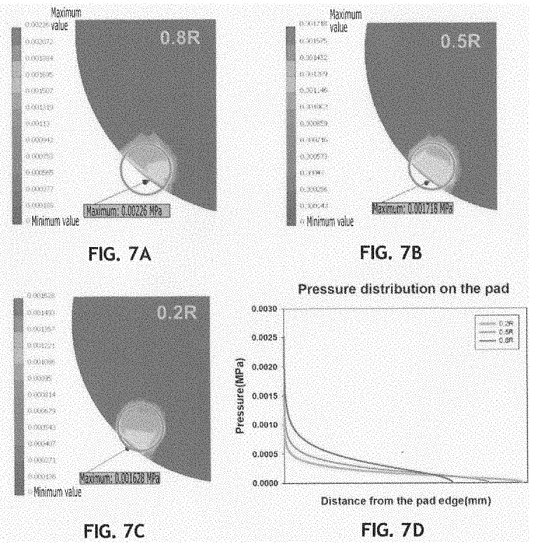

FIGS. 6A and 6B, and 7A, 7B, 7C, and 7D illustrate features according to a pressure distribution in the example simulation method to condition the example polishing pad, in accordance with one or more embodiments.

Specifically, FIGS. 6A and 6B illustrates a principle of a different pressure distribution, and FIGS. 7A-7D illustrate pressures according to distances (0.8 R, 0.5 R, and 0.2 R) at which the conditioner 100 deviates from the pad 200.

The example simulation method to condition the example polishing pad, in accordance with one or more embodiments may include an operation (operation S110, FIG. 4) of inputting the above-described first characteristic information, second characteristic information, and third characteristic information to an algorithm.

In accordance with one or more embodiments, the algorithm may derive a trajectory of grinding the pad by each diamond grit included in the conditioner 100 based on, for example, the first characteristic information, the second characteristic information, and the third characteristic information. Additionally, the algorithm may calculate grinding amount information on the amount of grinding the polishing pad 200 by each grit based on, for example, the trajectory, the first characteristic information, the second characteristic information, and the third characteristic information.

Additionally, although described in detail in, for example, operations S121 to S122 of FIG. 4 to be described below, the algorithm may determine coordinates of each diamond grit included in the conditioner 100 and determine a pressure and an indentation depth for each grit based on the first characteristic information, the second characteristic information, and the third characteristic information.

Additionally, the algorithm may accumulate a wear density based on, for example, the determined coordinates, and the pressure and indentation depth according to the coordinates to calculate an amount of grinding of the polishing pad 200 by each grit of the conditioner 100. However, the examples are not limited thereto.

In accordance with one or more embodiments, the inputting operation (operation S110) may further input characteristic information according to a pressure distribution applied to the polishing pad 200 to the algorithm. This may be to reflect the pressure applied to the polishing pad 200 by the conditioner 100 with respect to the edge of the polishing pad 200 when the conditioner 100 passes through the edge of the polishing pad 200. However, the examples are not limited thereto.

Referring to FIG. 7, when the conditioner 100 passes through the edge of the polishing pad 200, the edge of the polishing pad 200 may have the greatest pressure. This pressure may be a factor that is directly related to the amount of grinding of the polishing pad 200 by the conditioner 100.

Specifically, when the conditioner 100 is removed at a large distance in the edge direction of the polishing pad 200, the pressure on the edge of the polishing pad 200 further increases. Accordingly, in the simulation method to condition the polishing pad, in accordance with one or more embodiments, the pressure distribution according to the position of the conditioner 100, that is, the distance from the polishing pad 200 is input to the algorithm, thereby providing a simulation result with higher reliability and accuracy. However, the examples are not limited thereto.

Meanwhile, in accordance with one or more embodiments, the pressure distribution may be calculated through Equations 1 and 2 below.

$$tan ( θ ) = \frac{2 F ( 1 - {v}^{2} )}{π {a}^{2} E} \qquad Equation 1$$

In Equation 1 above and Equation 2 below, a may represent a contact radius, F may represent a force, v may represent a poisson rate, θ may represent an angle between a plane and a side, E may represent a young's modulus, and r may represent a distance from the edge.

$$p ( r ) = \frac{E tan ( θ )}{2 ( 1 - {v}^{2} )} {cosh}^{- 1} ( \frac{a}{r} ) \qquad Equation 2$$

In an example, a pressure distribution according to a distance from an edge may be obtained using Equations 1 and 2 above. Accordingly, the calculated graph may be illustrated in FIG. 7D. However, the examples are not limited thereto.

Additionally, in an example, the operation (operation S110) of inputting to the algorithm may further input characteristic information of the slurry including a change in physical properties of the pad 200 by the slurry used to condition the polishing pad 200.

The slurry is a polishing material implemented in a CMP process that polishes a semiconductor surface by a chemical or mechanical method, and may include an aqueous solution that contains chemical additives and polishing particles dispersed with fine particles.

The slurry used in the CMP process may vary according to a film to be polished and a polishing efficiency difference may be large by particle properties (shape, size, and size distribution) in a milling process, and thus, slurry containing various additives may be present according to a type of slurry. In an example, in the example of a metal thin film, since an oxide film may have lower mechanical hardness than metal, the surface may be oxidized using an oxidizing agent and then may be mechanically polished using a polishing agent so that a slurry additive may have a greater impact on a removal rate than the concentration of the polishing agent.

Accordingly, the simulation method to condition the polishing pad, in accordance with one or more embodiments, may provide a simulation result with higher reliability and accuracy by further inputting slurry characteristic information including a change in physical properties of the polishing pad due to the slurry. However, the examples are not limited thereto.

The simulation method to condition the polishing pad, in accordance with one or more embodiments, may include an operation (operation S120) of calculating a profile of the polishing pad 200.

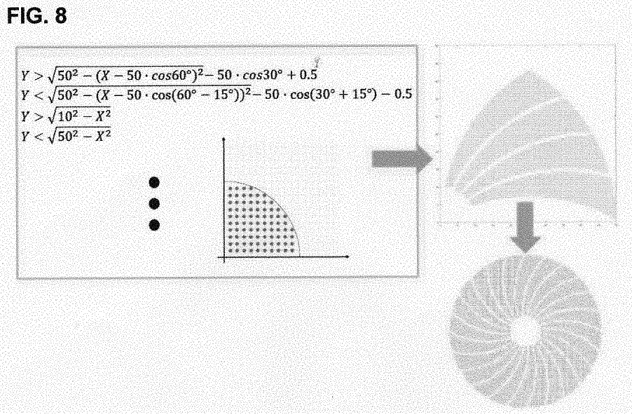

FIG. 8 illustrates an example of determining diamond grit coordinates included in the conditioner 100 in the simulation method to condition the polishing pad, in accordance with one or more embodiments.

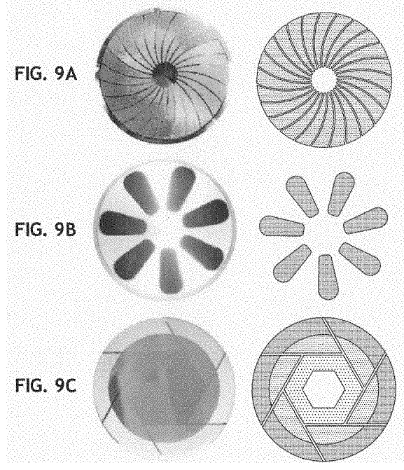

FIGS. 9A to 9C illustrate the determining of coordinates according to second characteristic information in the simulation method to condition the polishing pad, in accordance with one or more embodiments.

In one or more examples, the calculating operation (operation S120) may include an operation (operation S121) of determining coordinates of each diamond grit included in the conditioner 100, determining a pressure on each diamond grit, and determining an indentation depth for each grit.

Referring to FIG. 8, in accordance with one or more embodiments, in the determining operation (operation S121), the determining of the coordinates of each diamond grit included in the conditioner 100 may be determining the coordinates by applying the second characteristic information to the algorithm.

Referring to FIGS. 8 and 9A to 9C, in accordance with one or more embodiments, the coordinates of each diamond grit included in the conditioner 100 calculated based on the second characteristic information may be differently determined. Accordingly, it can be understood that the coordinates of each grit may be determined differently according to the type of the second characteristic information including the structure information on the conditioner 100.

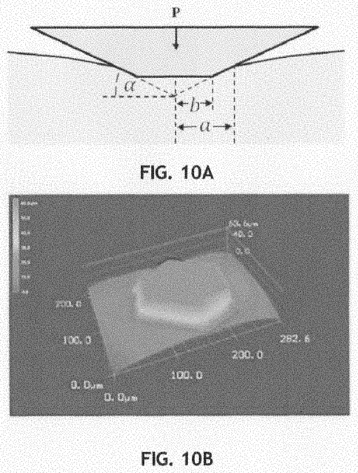

FIGS. 10A and 10B are a schematic diagrams illustrating the measuring of the size and the contact area of a diamond grit of the conditioner 100, and the calculating of an indentation depth according to the size and the contact area in the simulation method to condition the polishing pad, in accordance with one or more embodiments.

Referring to FIGS. 10A and 10B, pressures on the plurality of diamond grits included in the conditioner 100, in accordance with one or more embodiments, may be determined through Equation 3 below. Additionally, the indentation depth for each grit of the diamond included in the conditioner 100 may be determined through Equation 4 below.

$$p = 2 E α {\int }_{b}^{a} \frac{{r}^{2} dr}{\sqrt{{a}^{2} - {r}^{2}}} \qquad Equation 3$$

In Equation 3 above and Equation 4 below, E may represent a young's modulus of the polishing pad 200, a (A) may represent a contact radius, a (alpha) may represent an angle between a plane and a side of the grit, and p may represent a load pressure of each diamond grit.

$$Δ = α a {\int }_{b}^{a} \frac{{r}^{2} dr}{\sqrt{{a}^{2} - {r}^{2}}} \qquad Equation 4$$

In the simulation method to condition the polishing pad, in accordance with one or more embodiments, the calculating operation (operation S120) may include an operation (operation S122) of accumulating a wear density in a mesh corresponding to the coordinates of each grit of the diamond included in the conditioner 100.

In the accumulating operation (operation S122), in an example, the wear density in each grit may be accumulated based on the pressure and the indentation depth corresponding to the coordinates of each grit of each diamond, and the third characteristic information, thereby providing a simulation result with high reliability and accuracy.

In an example, in the operation (operation S120) of calculating the profile of the polishing pad 200, the profile of the polishing pad 200 may include, in an example, a wear density in the polishing pad 200, a trajectory of each diamond grit included in the conditioner 100, and cumulative moving distance information of the grit.

In an example, the simulation method to condition the polishing pad, in accordance with one or more embodiments, may include an operation (operation S130) of visualizing data based on the profile of the polishing pad 200 calculated in the calculating operation (operation S120).

The visualizing operation (operation S130) may be, in an example, visualizing a height of the pad 200 according to a radius coordinate of the polishing pad 200 as a graph. Additionally, according to the first characteristic information to the third characteristic information, the trajectory of grinding the polishing pad 200 by the diamond, the position of the conditioner 100 according to an operating time, the profile and the wear density of the polishing pad 200 after the operating time, the trajectory of diamonds of the conditioner 100, and the cumulative moving distance for each grit may be visualized. However, the examples are not limited thereto. In other words, in an example, the visualizing operation (operation S130) may visualize the information derived using the simulation method to condition the polishing pad 200 so that users may easily recognize the results at a glance, or may quickly acquire information.

Hereinafter, a simulation result implementing the example simulation method to condition the polishing pad 200, in accordance with one or more embodiments, will be described.

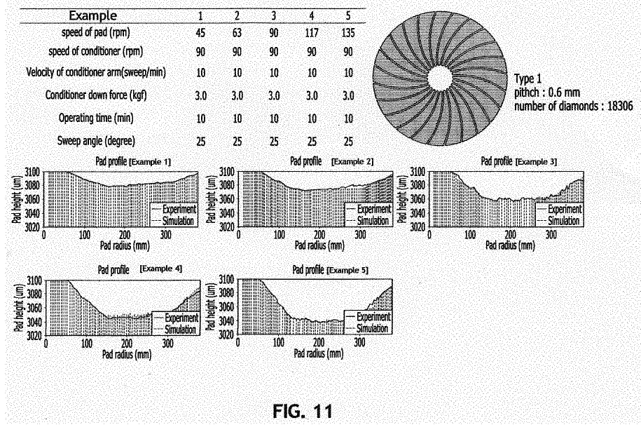

FIG. 11 illustrates a first simulation result implementing the example simulation method to condition the polishing pad 200, in accordance with one or more embodiments.

Referring to FIG. 11, in the example simulation method to condition the polishing pad 200, in accordance with one or more embodiments, a result of simulating the conditioning process using second characteristic information of the conditioner 100 of Type A in third characteristic information of the polishing pad 200 named GnP Poly 762, is illustrated.

As illustrated in FIG. 11, respective examples (Example 1 to Example 5) were applied by reflecting third characteristic variables differently. Accordingly, a result derived implementing the simulation method to condition the polishing pad may be understood to secure the profile and reliability and accuracy of the actual pad.

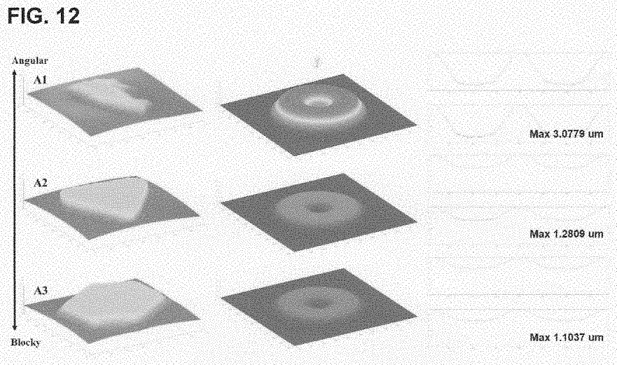

FIG. 12 illustrates a second simulation result implementing the simulation method to condition the polishing pad, in accordance with one or more embodiments.

Referring to FIG. 12, in the example simulation method to condition the polishing pad, in accordance with one or more embodiments, a simulation result according to an angular or blocky shape (form) of each grit of the conditioner 100 may be understood. That is, when the shape of each diamond grit included in the conditioner 100 is more blocky, it may be understood that the groove of the polishing pad is formed lower.

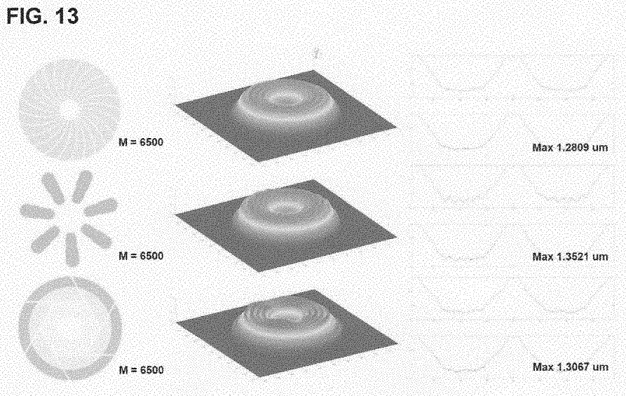

FIG. 13 illustrates a third simulation result implementing the simulation method to condition the polishing pad, in accordance with one or more embodiments.

Referring to FIG. 13, in the example simulation method to condition the polishing pad, in accordance with one or more embodiments, a simulation result according to a pattern of the conditioner 100 may be understood.

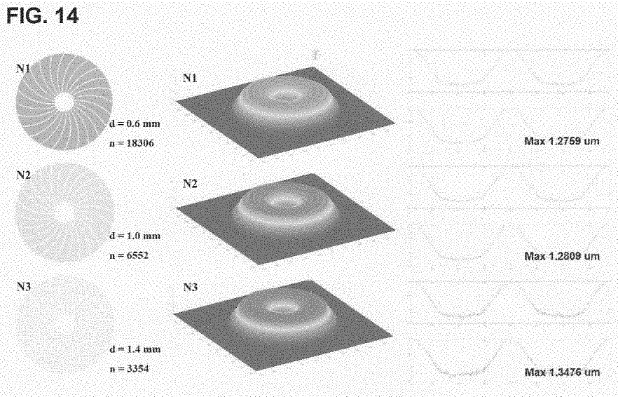

FIG. 14 illustrates a fourth simulation result implementing the example simulation method to condition the polishing pad 200, in accordance with one or more embodiments.

Referring to FIG. 14, in the example simulation method to condition the polishing pad, in accordance with one or more embodiments, a simulation result according to a distance d between diamonds and the number n of diamonds included in the conditioner 100 may be understood.

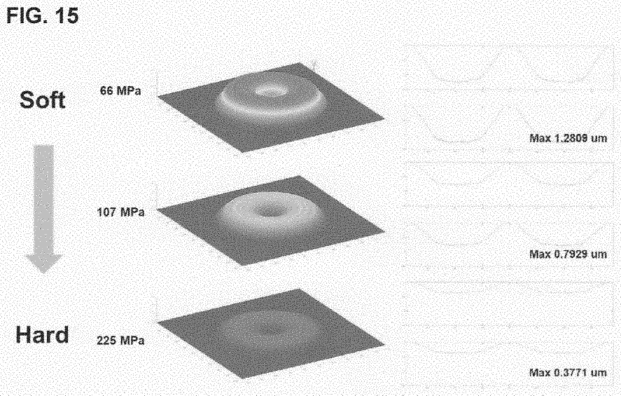

FIG. 15 illustrates a fifth simulation result implementing the example simulation method to condition the polishing pad, in accordance with one or more embodiments.

Referring to FIG. 15, in the example simulation method to condition the polishing pad, in accordance with one or more embodiments, a simulation result derived by varying the hardness of the polishing pad 200 may be understood. That is, it can be understood that the higher the hardness of the polishing pad 200, the lower the groove of the polishing pad 200.

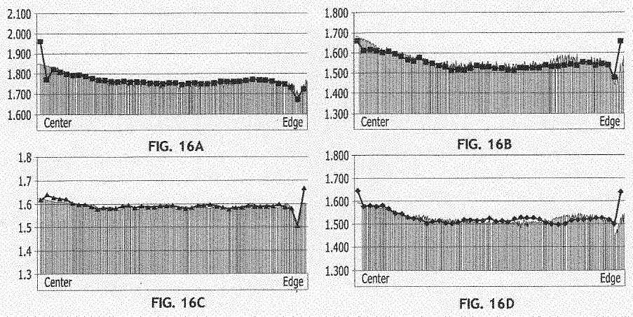

FIGS. 16A to 16D illustrate results of comparing a profile of an actual polishing pad with a sixth simulation result implementing the simulation method to condition the polishing pad, in accordance with one or more embodiments.

Referring to FIG. 16, even when the simulation method to condition the polishing pad, in accordance with one or more embodiments is applied according to the type of the polishing pad 200, a simulation result with high reliability and accuracy with respect to the edge of the polishing pad 200 may be understood.

Hereinafter, a simulation apparatus to condition a polishing pad will be briefly described based on the details described above.

The simulation apparatus to condition the polishing pad, in accordance with one or more embodiments may perform the simulation method to condition the polishing pad described above. Accordingly, even if omitted below, the description of the simulation method to condition the polishing pad may be equally applied even to the description of the simulation apparatus to condition the polishing pad.

The simulation apparatus for conditioning the polishing pad according to the exemplary embodiment of the present disclosure may include an extraction unit for extracting first characteristic information including progress parameters for the conditioning, second characteristic information including structure information of the conditioner, and third characteristic information including structure information of the polishing pad, a calculation unit for calculating a profile of the polishing pad by inputting the first characteristic information, the second characteristic information, and the third characteristic information to an algorithm, and a visualization unit for visualizing data based on the profile of the polishing pad.

In the above description, the simulation apparatus to condition the polishing pad may be further divided to additional components or may be combined with less components, in accordance with one or more embodiments. In addition, some components may be omitted or added if necessary.

The simulation method to condition the polishing pad, in accordance with one or more embodiments, may be implemented in the form of program instructions which may be performed through various computer means to be recorded in a computer readable medium. Instructions or software to control computing hardware, for example, one or more processors or computers, to implement the hardware components and perform the methods as described above may be written as computer programs, code segments, instructions or any combination thereof, for individually or collectively instructing or configuring the one or more processors or computers to operate as a machine or special-purpose computer to perform the operations that are performed by the hardware components and the methods as described above. In one example, the instructions or software include machine code that is directly executed by the one or more processors or computers, such as machine code produced by a compiler. In another example, the instructions or software includes higher-level code that is executed by the one or more processors or computer using an interpreter. The instructions or software may be written using any programming language based on the block diagrams and the flow charts illustrated in the drawings and the corresponding descriptions in the specification, which disclose algorithms for performing the operations that are performed by the hardware components and the methods as described above.

The instructions or software to control computing hardware, for example, one or more processors or computers, to implement the hardware components and perform the methods as described above, and any associated data, data files, and data structures, may be recorded, stored, or fixed in or on one or more non-transitory computer-readable storage media. Examples of a non-transitory computer-readable storage medium include read-only memory (ROM), random-access programmable read only memory (PROM), electrically erasable programmable read-only memory (EEPROM), random-access memory (RAM), dynamic random access memory (DRAM), static random access memory (SRAM), flash memory, non-volatile memory, CD-ROMs, CD-Rs, CD+Rs, CD-RWs, CD+RWs, DVD-ROMs, DVD-Rs, DVD+Rs, DVD-RWs, DVD+RWs, DVD-RAMs, BD-ROMs, BD-Rs, BD-R LTHs, BD-REs, blue-ray or optical disk storage, hard disk drive (HDD), solid state drive (SSD), flash memory, a card type memory such as multimedia card micro or a card (for example, secure digital (SD) or extreme digital (XD)), magnetic tapes, floppy disks, magneto-optical data storage devices, optical data storage devices, hard disks, solid-state disks, and any other device that is configured to store the instructions or software and any associated data, data files, and data structures in a non-transitory manner and provide the instructions or software and any associated data, data files, and data structures to one or more processors or computers so that the one or more processors or computers can execute the instructions. In one example, the instructions or software and any associated data, data files, and data structures are distributed over network-coupled computer systems so that the instructions and software and any associated data, data files, and data structures are stored, accessed, and executed in a distributed fashion by the one or more processors or computers.

Further, the aforementioned simulation method to condition the polishing pad may be implemented even in the form of computer programs or applications to be executed by a computer, which are stored in the recording medium.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

Therefore, the scope of the disclosure is defined not by the detailed description, but by the claims and their equivalents, and all variations within the scope of the claims and their equivalents are to be construed as being included in the disclosure.

What is claimed is:

1. A polishing pad conditioning simulation method, comprising:
extracting first characteristic information comprising process parameters of the conditioning, extracting second characteristic information comprising structure information of a conditioner, and extracting third characteristic information comprising structure information of the polishing pad;
inputting the first characteristic information, the second characteristic information, and the third characteristic information to an algorithm;
calculating a profile of the polishing pad; and
outputting data based on the calculated profile of the polishing pad.

2. The method of claim 1, wherein the inputting to the algorithm further comprises inputting characteristic information based on a pressure distribution applied to the polishing pad to the algorithm.

3. The method of claim 2, wherein the inputting to the algorithm further comprises inputting slurry characteristic information comprising a change in physical properties of the polishing pad by slurry implemented in the conditioning of the polishing pad.

4. The method of claim 1, wherein the calculating comprises determining coordinates of diamond grits comprised in the conditioner, determining a pressure on each diamond grit, and determining an indentation depth for each diamond grit.

5. The method of claim 4, wherein the calculating comprises accumulating a wear density in a mesh corresponding to the coordinates of each grit of the diamond comprised in the conditioner.

6. The method of claim 1, wherein the algorithm is configured to:
derive a trajectory of grinding the pad by diamond grits of the conditioner based on the first characteristic information, the second characteristic information, and the third characteristic information, and
calculate grinding amount information on an amount of grinding of the polishing pad by each grit of the diamond based on the trajectory, the first characteristic information, the second characteristic information, and the third characteristic information.

7. The method of claim 1, wherein the profile of the polishing pad comprises a wear density in the polishing pad, a trajectory of diamond grits of the conditioner, and cumulative moving distance information of each diamond.

8. The method of claim 1, wherein:
the structure information of the conditioner is extracted based on an apparatus comprising confocal microscopy and atomic force microscopy (AFM);
the first characteristic information comprises rotation speed information of the polishing pad and the conditioner, sweep arm operation information, pressure information, and press time information;
the second characteristic information comprises density and size information of the conditioner, and diamond information, and
the third characteristic information comprises groove information, hardness information, and size information of the polishing pad.

9. A non-transitory computer-readable storage medium storing instructions that, when executed by a processor, cause the processor to perform the method of claim 1.

10. A polishing pad conditioning simulation apparatus, comprising:
an extraction device configured to extract first characteristic information comprising progress parameters for the conditioning, extract second characteristic information comprising structure information of a conditioner, and extract third characteristic information comprising structure information of the polishing pad;
a calculation device configured to calculate a profile of the polishing pad by inputting the first characteristic information, the second characteristic information and the third characteristic information to an algorithm; and
a display unit configured to display data based on the calculated profile of the polishing pad.

11. The apparatus of claim 10, wherein the calculation device is configured to calculate the profile of the polishing pad by further inputting characteristic information according to a pressure distribution applied to the polishing pad to the algorithm.

12. The apparatus of claim 11, wherein the calculation device is configured to calculate the profile of the polishing pad by further inputting slurry characteristic information comprising a change in physical properties of the polishing pad by slurry implemented in the conditioning of the polishing pad.

13. The apparatus of claim 12, wherein the calculation device is configured to determine coordinates of diamond grits comprised in the conditioner, determine a pressure on each diamond grit, and determine an indentation depth for each diamond grit.

14. The apparatus of claim 13, wherein the calculation device is configured to accumulate a wear density in a mesh corresponding to the coordinates of each grit of the diamond comprised in the conditioner.

15. The apparatus of claim 10, wherein the algorithm is configured to:
derive a trajectory of grinding the pad by diamond grits of the conditioner based on the first characteristic information, the second characteristic information, and the third characteristic information, and
calculate grinding amount information on an amount of grinding of the polishing pad by each grit of the diamond based on the trajectory, the first characteristic information, the second characteristic information, and the third characteristic information.

16. The apparatus of claim 10, wherein the profile of the polishing pad comprises a wear density in the polishing pad, a trajectory of each diamond grit of the conditioner, and cumulative moving distance information of each diamond.

17. The apparatus of claim 10, wherein:
the structure information is extracted based on an apparatus comprising confocal microscopy and atomic force microscopy (AFM);
the first characteristic information comprises rotation speed information of the polishing pad and the conditioner, sweep arm operation information, pressure information, and press time information,
the second characteristic information comprises density and size information of the conditioner, and diamond information, and
the third characteristic information comprises groove information, hardness information, and size information of the polishing pad.
